(19) United States
(12) Patent Application Publication
(10) Pub. No.: US 2022/0102206 A1
(43) Pub. Date: Mar. 31, 2022

(54) SEMICONDUCTOR DEVICE, MANUFACTURING METHOD OF SEMICONDUCTOR DEVICE, AND STORAGE DEVICE

(71) Applicant: CHANGXIN MEMORY TECHNOLOGIES, INC., Hefei City (CN)

(72) Inventor: Xing JIN, Hefei (CN)

(21) Appl. No.: 17/504,581

(22) Filed: Oct. 19, 2021

Related U.S. Application Data
(63) Continuation of application No. PCT/CN2021/106926, filed on Jul. 16, 2021.

(30) Foreign Application Priority Data
Sep. 27, 2020 (CN) 202011033098.2

(51) Int. Cl. H01L 21/768; H01L 27/108; H01L 23/532

(52) U.S. Cl. CPC H01L 21/76834; H01L 27/10888; H01L 27/10823; H01L 23/53295; H01L 21/76832; H01L 27/10885

(57) ABSTRACT

A semiconductor device, a manufacturing method of the semiconductor device, and a storage device are provided. The method includes: providing a semiconductor substrate having multiple first areas and multiple second areas arranged alternately and adjacent to each other; forming on the semiconductor substrate laminated structures each intersecting with the first areas and the second areas; forming side wall structures on surfaces of the laminated structures; filling a sacrificial layer; etching the side wall structures in the first areas so that the laminated structure and the side wall structure form a step shape with the middle higher than both sides of the step shape; forming dielectric layers on the semiconductor substrate in the first areas; and flattening the dielectric layers and the bit lines to remove part of each of the dielectric layers and part of each of the laminated structures on a side away from the semiconductor substrate.

### CROSS-REFERENCE TO RELATED APPLICATION

This is a continuation application of International Patent Application No. PCT/CN2021/106926, filed on Jul. 16, 2021, which claims priority to Chinese Patent Application No. 202011033098.2, filed on Sep. 27, 2020 and entitled “Semiconductor Device, Manufacturing Method of Semiconductor Device, and Storage Device”. The disclosures of International Patent Application No. PCT/CN2021/106926 and Chinese Patent Application No. 202011033098.2 are incorporated by reference herein in their entireties.

### BACKGROUND

A Dynamic Random Access Memory (DRAM) is a commonly used semiconductor storage device in computers, and is composed of many storage units arranged in an array. Each of the storage units may usually include a capacitor and a transistor. A gate of the transistor is connected with a word line, a drain of the transistor is connected with a bit line, and a source of the transistor is connected with the capacitor. Voltage signals on the word line may control the transistor to be turned on or turned off, so that the data information stored in the capacitor may be read through the bit line, or the data information may be written into the capacitor through the bit line for storage.

With the development of science and technology, the storage unit of the DRAM is reduced to about 20 nm, which requires higher requirements for the manufacturing process. In the manufacturing process of the storage unit of the DRAM, due to the continuous reduction of the process size and the progress of a process technology, the insulation performance of an insulating layer is also improving. However, the related art is easy to cause parasitic capacitance or short circuiting of a capacitor contact hole, thereby reducing the yield of the DRAM.

It is to be noted that information disclosed in the above background part is merely used for enhancing understanding of the background of the disclosure, and thus the information, which does not constitute the related art known by those of ordinary skill in the art, may be included.

### SUMMARY

The disclosure relates to the technical field of semiconductors, and in particular relates to a semiconductor device, a manufacturing method of the semiconductor device, and a storage device including the semiconductor device.

According to a first aspect of the disclosure, there is provided a manufacturing method of a semiconductor device which may include the following operations.

A semiconductor substrate having a plurality of first areas and a plurality of second areas arranged alternately and adjacent to each other is provided.

Laminated structures each intersecting with the first areas and the second areas are formed on the semiconductor substrate.

Side wall structures are formed on surfaces of the laminated structures, in which the side wall structures and the laminated structures form bit lines.

A sacrificial layer having a height greater than or equal to a height of the bit lines is filled.

Each of the side wall structures in each of the first areas is etched, so that the laminated structure and the side wall structure form a step shape with a middle higher than both sides of the step shape.

Dielectric layers having a height greater than or equal to the height of the bit lines are formed on the semiconductor substrate in the first areas.

The dielectric layers and the bit lines are flattened to remove a part of each of the dielectric layers and a part of each of the laminated structures on a side away from the semiconductor substrate.

According to a second aspect of the disclosure, there is provided a semiconductor device, which may include a semiconductor substrate, laminated structures, side wall structures and dielectric layers.

The semiconductor substrate is provided with a plurality of first areas and a plurality of second areas arranged alternately and adjacent to each other.

The laminated structures are arranged on the semiconductor substrate, and each intersect with the first areas and the second areas.

The side wall structures are arranged on sidewalls of the laminated structures, the laminated structure and the side wall structure located in each of the first areas are arranged in a step shape with a middle higher than both sides of the step shape, and the laminated structures and the side wall structures form bit lines.

The dielectric layers are arranged on the semiconductor substrate and each located in the first area between the bit lines, and the dielectric layers are connected with the bit lines to form a plurality of capacitor contact holes.

According to a third aspect of the disclosure, there is provided a storage device including a semiconductor device according to any one of the above embodiments.

### BRIEF DESCRIPTION OF THE DRAWINGS

The drawings here, which are incorporated into this specification and constitute a part of this specification, illustrate embodiments according to the disclosure and, together with the specification, serve to explain the principles of the disclosure. It is apparent that the drawings described below are only some embodiments of the disclosure. Other drawings may further be obtained by those of ordinary skilled in the art according to these drawings without creative work.

FIG. 1 is a schematic structural diagram of an exemplary implementation mode of a semiconductor device in a related art.

FIG. 2 is a schematic structural diagram of another exemplary implementation mode of a semiconductor device in a related art.

FIG. 3 is a schematic structural diagram illustrating that a dielectric layer is formed based on FIG. 2.

FIG. 4 is a schematic flow block diagram of an exemplary implementation mode of a manufacturing method of a semiconductor device of the disclosure.

FIG. 5 is a schematic structural diagram of a semiconductor substrate in a semiconductor device of the disclosure.

FIG. 6 is a schematic structural diagram after a laminated structure is formed based on FIG. 5.

FIG. 7 is a schematic top view of FIG. 6.

FIG. 8 is a schematic structural diagram after a first side wall material layer is formed based on FIG. 6.

FIG. 9 is a schematic structural diagram after a first side wall is formed based on FIG. 8.

FIG. 10 is a schematic structural diagram after a second side wall material layer is formed based on FIG. 8.

FIG. 11 is a schematic structural diagram illustrating that a second side wall is formed after a second side wall material layer is etched based on FIG. 10.

FIG. 12 is a schematic structural diagram after a sacrificial layer is filled based on FIG. 11.

FIG. 13 is a schematic structural diagram after a sacrificial layer is flattened based on FIG. 12.

FIG. 14 is a schematic structural diagram after a first side wall and a second side wall are etched based on FIG. 13.

FIG. 15 is a schematic structural diagram after a first side wall is etched based on FIG. 14.

FIG. 16 is a schematic structural diagram after a second side wall, a protective layer and a sacrificial layer are etched based on FIG. 15.

FIG. 17 is a schematic three-dimensional structural diagram of FIG. 16.

FIG. 18 is a schematic structural diagram after a dielectric layer is formed based on FIG. 16.

FIG. 19 is a schematic structural diagram of a semiconductor device of the disclosure formed based on FIG. 11.

### DETAILED DESCRIPTION

Exemplary implementation modes are described more comprehensively with reference to the drawings at present. However, the exemplary implementation modes may be implemented in many forms, and should not be understood as limitation to implementation modes described here. On the contrary, the provision of these implementation modes enables the disclosure to be more comprehensive and complete, and conceptions of the exemplary implementation modes are comprehensively conveyed to those skilled in the art. The same signs in the drawings show same or similar structures, and thus detailed description of them is omitted.

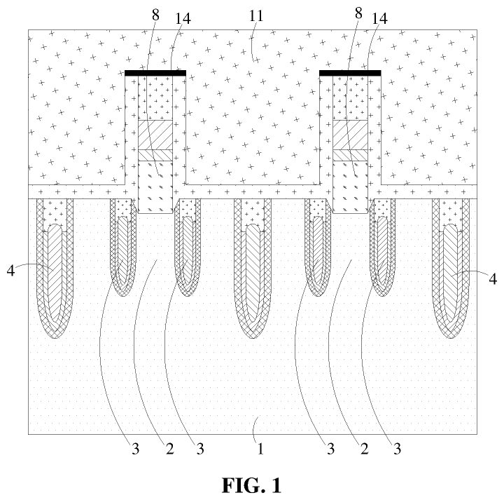

Referring to the schematic structural diagram of an exemplary implementation mode of a semiconductor device in a related art shown in FIG. 1, in the manufacturing process of a capacitor contact hole of a DRAM, a hole like capacitor contact hole will be formed due to a bit line 8, and a top dielectric layer 54 of the bit line 8 will be inevitably consumed in the etching process of the capacitor contact hole. The material of the top dielectric layer 54 may be silicon nitride. If the top dielectric layer 54 is consumed too much, and a dielectric layer 11 is refilled subsequently, in which the material of the dielectric layer 11 may also be silicon nitride, a thin boundary layer 14 then will be formed between contact surfaces of the two layers of silicon nitride due to different polymers or different shrinkage ratios, which will lead to the decline of the insulation performance of a semiconductor device, and will also increase the risk of production of parasitic capacitance.

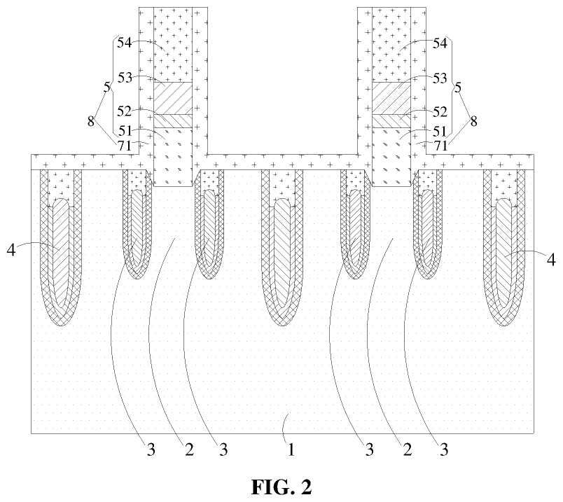

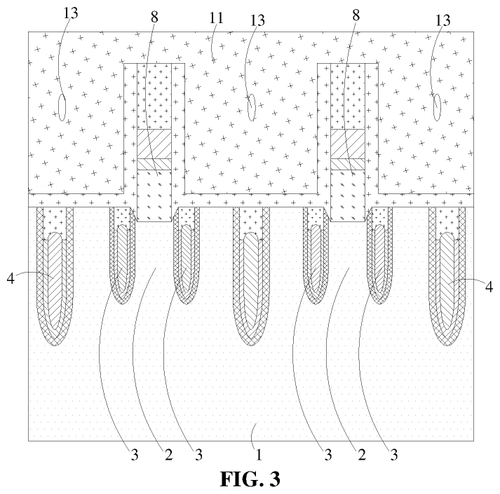

Referring to the schematic structural diagram of another exemplary implementation mode of a semiconductor device in a related art shown in FIG. 2 and FIG. 3, if more top dielectric layer 54 of the bit line 8 is reserved by controlling the selection ratio, a structure with high depth-to-width ratio will be formed, which will result in that a void 13 is easily formed near the semiconductor substrate 1 in the subsequently filled dielectric layer 11, and cannot be completely removed, and the void 13 will cause short circuiting of a capacitor contact hole and reduce the yield of a DRAM.

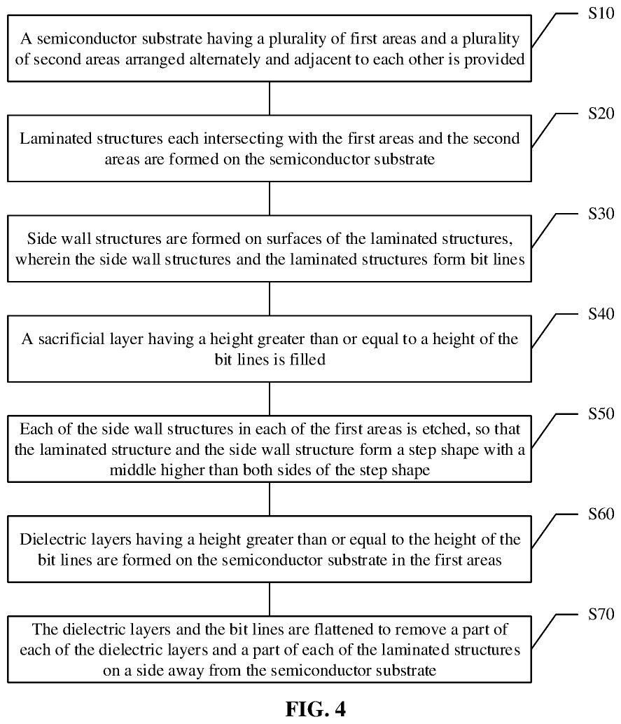

The exemplary implementation mode provides a manufacturing method of a semiconductor device at first. Referring to a schematic flow block diagram of an exemplary implementation mode of a manufacturing method of a semiconductor device of the disclosure shown in FIG. 4, the manufacturing method of the semiconductor device may include the following steps.

At S10, a semiconductor substrate having a plurality of first areas and a plurality of second areas arranged alternately and adjacent to each other is provided.

At S20, laminated structures each intersecting with the first areas and the second areas are formed on the semiconductor substrate.

At S30, side wall structures are formed on surfaces of the laminated structures, in which the side wall structures and the laminated structures form bit lines.

At S40, a sacrificial layer having a height greater than or equal to a height of the bit lines is filled.

At S50, each of the side wall structures in each of the first areas is etched, so that the laminated structure and the side wall structure form a step shape with a middle higher than both sides of the step shape.

At S60, dielectric layers having a height greater than or equal to the height of the bit lines are formed on the semiconductor substrate in the first areas.

At S70, the dielectric layers and the bit lines are flattened to remove a part of each of the dielectric layers and a part of each of the laminated structures on a side away from the semiconductor substrate.

Various steps of the manufacturing method of the semiconductor device are described in detail below.

At S10, a semiconductor substrate having a plurality of first areas and a plurality of second areas arranged alternately and adjacent to each other is provided.

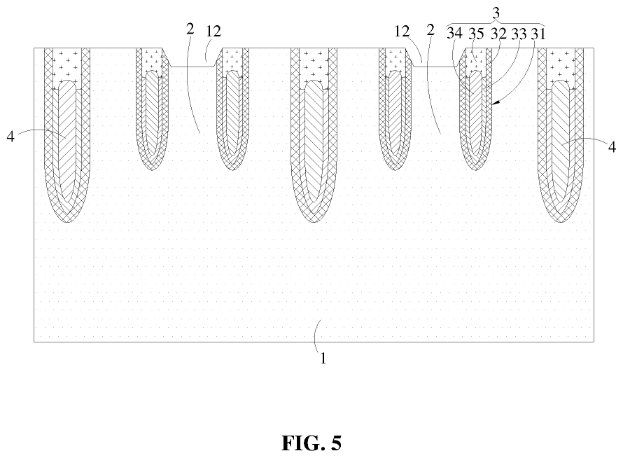

Referring to FIG. 5, in the exemplary implementation mode, the semiconductor substrate 1 may include, but is not limited to, a monocrystalline silicon substrate, a polysilicon substrate, a gallium nitride substrate or a sapphire substrate. In addition, when the semiconductor substrate 1 is a monocrystalline substrate or a polysilicon substrate, it may also be an intrinsic silicon substrate or a slightly doped silicon substrate, and furthermore, it may be an N-type polysilicon substrate or P-type polysilicon substrate.

A plurality of active areas 2 arranged in an array are formed in the semiconductor substrate 1. A plurality of parallel word lines 3 arranged at intervals are formed in the semiconductor substrate 1, and the extension direction of the word line 3 intersects with the extension direction of the active area 2 at an angle of less than 90 degrees.

In the exemplary implementation mode, a plurality of shallow trench isolation structures 4 are formed in the semiconductor substrate 1. The shallow trench isolation structure 4 may be formed by forming a trench in the semiconductor substrate 1 and then filling an isolation material layer in the trench. The material of the shallow trench isolation structure 4 may include silicon nitride or silicon oxide, etc. The section shape of the shallow trench isolation structure 4 can be set according to the actual needs. The shallow trench isolation structures 4 may isolate a plurality of active areas 2 on the semiconductor substrate 1.

The step that the plurality of parallel word lines 3 arranged at intervals are formed in the semiconductor substrate 1 may include the following operations.

Word line trenches 31 defining positions and shapes of the word lines 3 are formed in the semiconductor substrate 1. Specifically, the word line trenches 31 may be formed in the semiconductor substrate 1 by a photoetching process.

Inter-gate dielectric layers 32 are formed in the word line trenches 31, and the inter-gate dielectric layers 32 cover side walls and bottoms of the word line trenches 31. Specifically, the inter-gate dielectric layer 32 covers a lower sidewall and the bottom of the word line trench 31. The material of the inter-gate dielectric layer 32 may include, but is not limited to, at least one of silicon oxide and silicon nitride. The inter-gate dielectric layer 32 may be formed by using Atomic Layer Deposition (ALD), Chemical Vapor Deposition (CVD), or Rapid Thermal Oxidation (RTO).

First conductive layers 33 and second conductive layers 34 are formed in the word line trenches 31. The first conductive layer 33 covers a sidewall of the inter-gate dielectric layer 32 and a bottom of the inter-gate dielectric layer 32, the second conductive layer 34 fully fills a gap inside the first conductive layer 33, and an upper surface of each of the first conductive layer 33 and the second conductive layer 34 is lower than an upper surface of the semiconductor substrate 1. Furthermore, the upper surface of the second conductive layer 34 is higher than the upper surface of the first conductive layer 33. The material of the first conductive layer 33 may include any one of As or B-doped silicon, P or As doped germanium, W, Ti, TiN or Ru, the material of the second conductive layer 34 may include any one of W, Ti, Ni, Al or Pt, and the material of the first conductive layer 33 is different from the material of the second conductive layer 34. The first conductive layer 33 and the second conductive layer 34 may be formed by ALD or CVD.

Filling insulating layers 35 are formed in the word line trenches 31. The filling insulating layer 35 covers the upper surface of the first conductive layer 33 and the upper surface of the second conductive layer 34, and fully fills the word line trench 31. The material of the filling insulating layer 35 may include any suitable insulating material including oxides (such as silicon oxide, aluminium oxide or hafnium oxide, etc.), silicon nitride, silicon oxynitride, etc.

Finally, a part of each of the active areas 2 and a part of each of the shallow trench isolation structures 4 are removed by etching to form bit line contact trenches 12.

The semiconductor substrate has a plurality of first areas 151 and a plurality of second areas 152 arranged alternately and adjacent to each other. A dielectric hole may be formed in the first area 151 subsequently, and a capacitor contact hole may be formed in the second area 152 subsequently. In the exemplary implementation mode, the first area 151 and the second area 152 may be rectangular. Certainly, in other exemplary implementation modes of the disclosure, the first area 151 and the second area 152 each may also be a curved strip.

At S20, laminated structures each intersecting with the first areas and the second areas are formed on the semiconductor substrate.

In the exemplary implementation mode, a polysilicon material layer is deposited on the semiconductor substrate 1. The polysilicon material layer is preferably doped with polysilicon to increase its conductivity. A first conductor material layer is deposited on a side, away from the semiconductor substrate 1, of the polysilicon material layer, and the material of the first conductor material layer may be titanium nitride or tungsten silicide. A second conductor material layer is deposited on a side, away from the semiconductor substrate 1, of the first conductor material layer, and the material of the second conductor material layer may include, but is not limited to, tungsten. A top dielectric material layer is deposited on a side, away from the semiconductor substrate 1, of the second conductor material layer, and the material of the top dielectric material layer may include, but is not limited to, silicon nitride. A protective material layer is deposited on a side, away from the semiconductor substrate 1, of the top dielectric material layer, and the material of the protective material layer may be, but is not limited to, silicon dioxide.

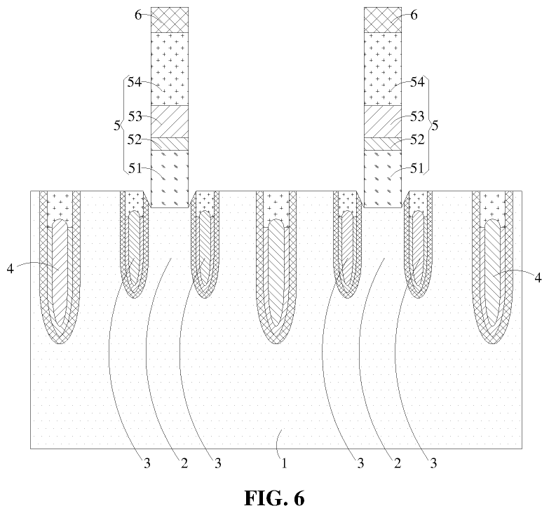

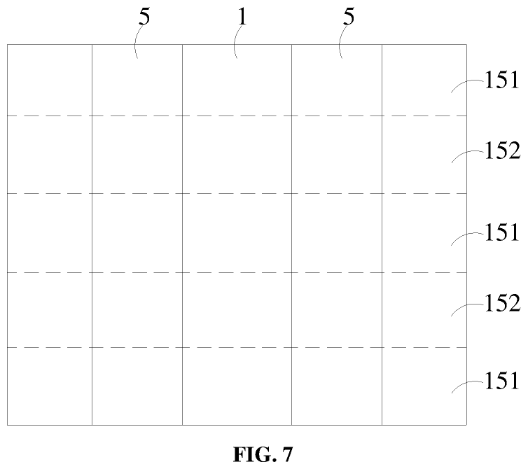

Referring to FIG. 6 and FIG. 7, the protective material layer, the top dielectric material layer, the second conductor material layer, the first conductor material layer and the polysilicon material layer are etched, so that the protective material layer, the top dielectric material layer, the second conductor material layer, the first conductor material layer and the polysilicon material layer at each of the bit line contact trenches 12 are retained to form a protective layer 6, a top dielectric layer 54, a second conductive layer 53, a first conductive layer 52 and a polysilicon layer 51 respectively, and the top dielectric layer 54, the second conductive layer 53, the first conductive layer 52 and the polysilicon layer 51 form a laminated structure 5. Referring to FIG. 7, the laminated structure 5 perpendicularly intersects with the first areas 151 and the second areas 152. Certainly, in other exemplary implementation modes of the disclosure, the laminated structure 5 may intersect with the first areas 151 and the second areas 152 at an acute angle.

At S30, side wall structures are formed on surfaces of the laminated structures, in which the side wall structures and the laminated structures form bit lines.

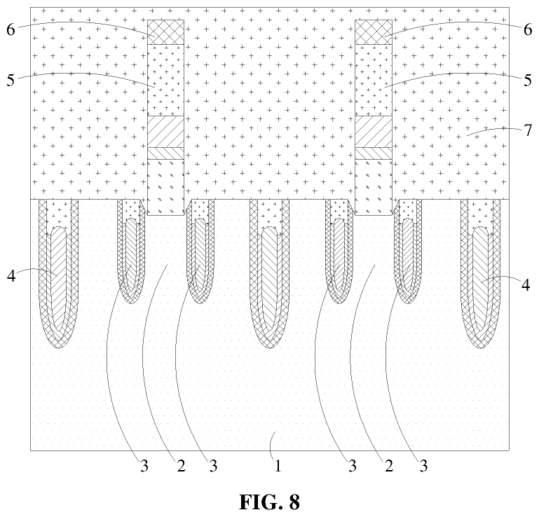

In the exemplary implementation mode, referring to FIG. 8, a first side wall material layer 7 is formed on the semiconductor substrate 1 by an ALD technology, and the material of the first side wall material layer 7 may be silicon nitride. A height of the first side wall material layer 7 is higher than a height of the protective layers 6, so that the first side wall material layer 7 completely covers the protective layer 6, the top dielectric layer 54, the second conductive layer 53, the first conductive layer 52 and the polysilicon layer 51.

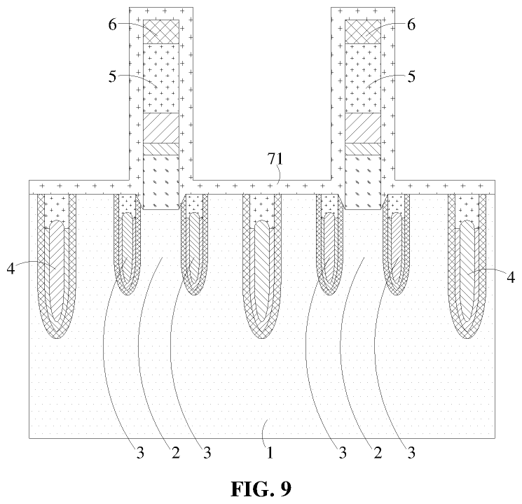

Referring to FIG. 9, the first side wall material layer 7 is then etched to form a first side wall 71. The first side wall 71 still completely covers the semiconductor substrate 1, the protective layer 6, the top dielectric layer 54, the second conductive layer 53, the first conductive layer 52 and the polysilicon layer 51 by a substantially same thickness. The thickness of the first side wall 71 is greater than or equal to 6 nm and less than or equal to 10 nm, such that a groove is formed between adjacent laminated structures 5. The first side wall 71 may protect the semiconductor substrate 1 thereby avoiding damage to the semiconductor substrate 1 in the subsequent etching process.

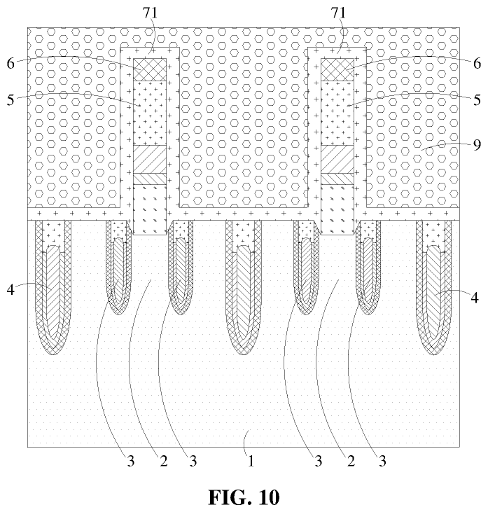

In the exemplary implementation mode, referring to FIG. 10, the manufacturing method may also include the following operations. A second side wall material layer 9 is formed on a side, away from the semiconductor substrate 1, of the first side wall 71 by the ALD technology, and the material of the second side wall material layer 9 may be silicon oxynitride. The height of the second side wall material layer 9 is greater than the height of the highest point of the first side wall 71, that is, the second side wall material layer 9 completely covers the first side wall 71.

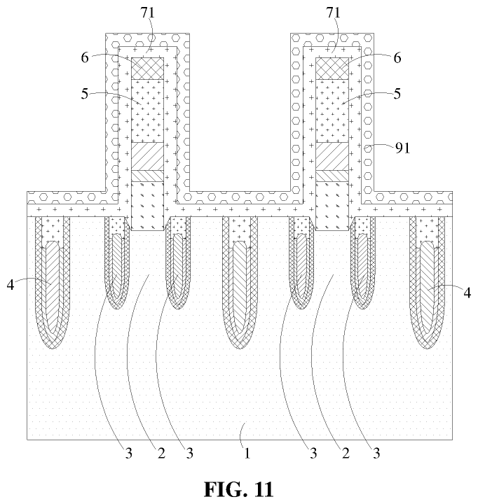

Referring to FIG. 11, the second side wall material layer 9 is then etched to form a second side wall 91. The second side wall 91 still completely covers the first side wall 71, and the covering thickness is substantially the same. The thickness of the second side wall 91 is greater than or equal to 6 nm and less than or equal to 10 nm, such that a groove is formed between adjacent laminated structures 5. The second side wall 91 may protect the semiconductor substrate 1, thereby avoiding damage to the semiconductor substrate 1 in the subsequent etching process.

It is to be noted that, the manufacturing process of each of the first side wall 71 and the second side wall 91 is not limited to the above description. For example, the first side wall 71 with the required thickness may be deposited directly without the need to perform the etching step, and then the second side wall 91 with the required thickness is deposited on a side, away from the semiconductor substrate 1, of the first side wall 71, and the etching step is also not necessary.

The laminated structure 5, the first side wall 71 and the second side wall 91 form a bit line 8. Certainly, the bit line 8 also intersects perpendicularly with the first areas 151 and the second areas 152.

The side wall structure in the exemplary implementation mode may include a first side wall 71 and a second side wall 91. In other exemplary implementation modes of the disclosure, the side wall structure may only include one layer of side wall, and may also include three layers or more layers of side walls.

At S40, a sacrificial layer having a height greater than or equal to the height of the bit line is filled.

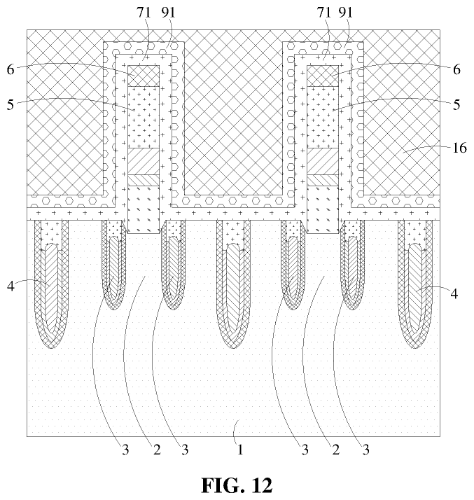

In the exemplary implementation mode, referring to FIG. 12, the groove formed in the second side wall 91 is filled with a sacrificial layer 16. The material of the sacrificial layer 16 is the same as that of the protective layer, both of which are silicon oxide. Moreover, the height of the sacrificial layer 16 may be greater than the depth of the groove, that is, the sacrificial layer 16 completely covers the second side wall 91.

Certainly, in other exemplary implementation modes of the disclosure, the height of the sacrificial layer 16 may be the same as the height of the highest point of the second side wall 91, that is, the sacrificial layer 16 does not cover the upper surface of the bit line.

At S50, each of the side wall structures in each of the first areas is etched, so that the laminated structure and the side wall structure form a step shape with a middle higher than both sides of the step shape.

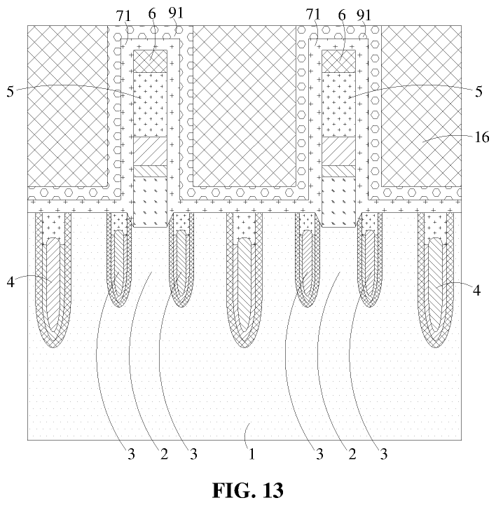

In the exemplary implementation mode, referring to FIG. 13, since the height of the sacrificial layer 16 is greater than the height of the highest point of the second side wall 91, it is necessary to flatten the sacrificial layer 16 at first. The flattening may be grinding by a chemical mechanical grinder to expose the second side wall 91 on a side, away from the semiconductor substrate 1, of the protective layer 6, that is, the upper surface of the second side wall 91 is exposed. Certainly, in other exemplary implementation modes of the disclosure, when the height of the sacrificial layer 16 is the same as that of the highest point of the second side wall 91, this step may not be performed.

Next, a mask layer (not shown in the figure) is formed on the sacrificial layer 16. An orthographic projection of the mask layer on the semiconductor substrate 1 is coincides with the second area 152. The mask layer protects the sacrificial layer 16 and the bit line 8 in the second area 152 from being etched.

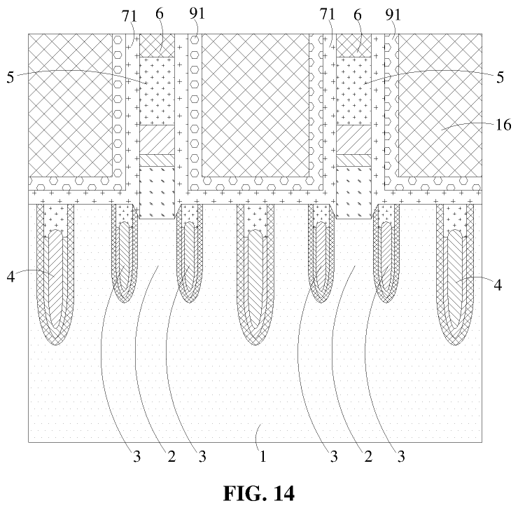

Referring to FIG. 14, the first side wall 71 and the second side wall 91 in the first area 151 are etched by taking the mask layer as a mask until the upper surface of the protective layer 6 is exposed.

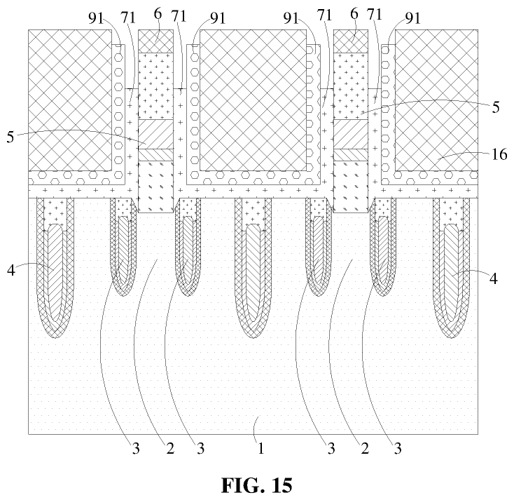

Referring to FIG. 15, the first side wall 71 is etched by taking the protective layer 6 as a mask by selecting an etching process in which the etching rate of the first side wall 71 (silicon nitride) is greater than the etching rate of each of the second side wall 91 (silicon oxynitride) and the sacrificial layer 16 (silicon oxide). In the etching process, the protective layer 6 (silicon oxide) will protect the top dielectric layer 54 (silicon nitride) of the laminated structure 5. The first side wall 71 is etched until the height of the first side wall 71 is lower than that of the laminated structure 5. The height difference H1 between the first side wall 71 and the laminated structure 5 is greater than or equal to 30 nm and less than or equal to 50 nm.

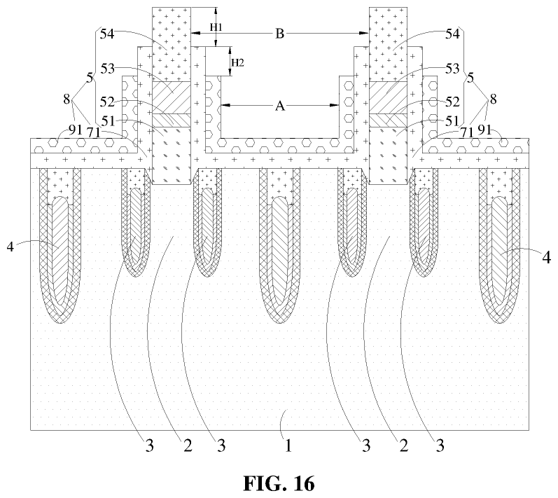

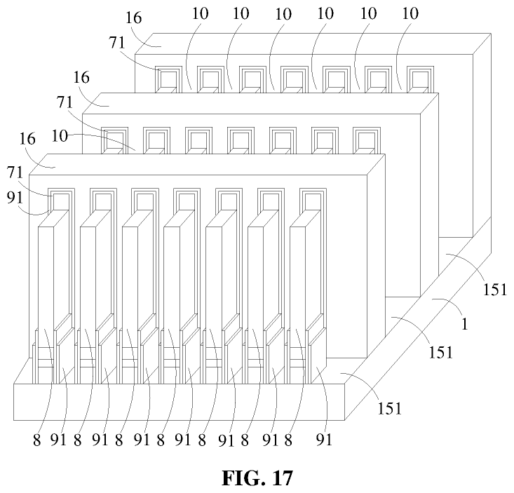

Referring to FIG. 16 and FIG. 17, the second side wall 91, the protective layer and the sacrificial layer 16 are etched by selecting a dry etching process in which the etching rate of the sacrificial layer 16 is greater than that of the second side wall 91 and the etching rate of the second side wall 91 is greater than that of the first side wall, so that the height of the second side wall 91 is lower than that of the first side wall. A height difference H2 between the first side wall 71 and the second side wall 91 is greater than or equal to 30 nm and less than or equal to 50 nm, so that the bit line 8 forms a step shape with the middle higher than both sides of the step shape, that is, the laminated structure 5 in the middle is the highest, the second side wall 91 is the lowest, and the height of the first side wall 71 is comprised between the height of the laminated structure 5 and the height of the second side wall 91. Because the etching rate of silicon oxide is the highest, the protective layer 6 and sacrificial layer 16 in the first area 151 will be removed simultaneously to form a dielectric hole.

Certainly, when there are three or more layers of side walls, the farther a side wall is from the laminated structure 5, the lower its height is.

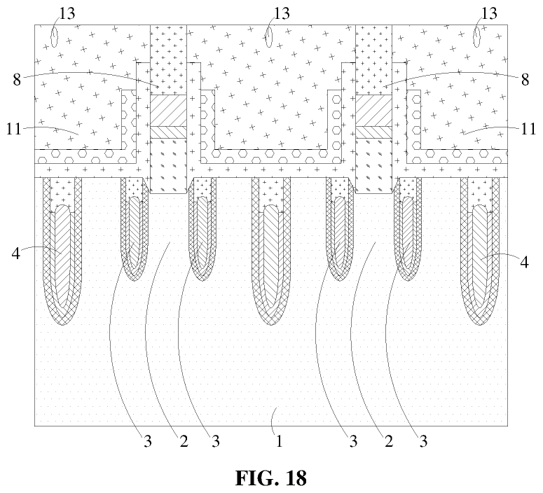

Next, referring to FIG. 18, dielectric layers 11 is deposited in dielectric holes 10. The material of the dielectric layer 11 may be silicon nitride. Since the gap between the two adjacent bit lines 8 forms a structure with a large top and a small bottom, when the dielectric layer 11 is formed in the dielectric hole 10, it is not easy to form a void 13 on a side close to the semiconductor substrate 1, and a void 13 may be formed in the dielectric layer 11 on a side away from the semiconductor substrate 1.

At S70, the dielectric layers and the bit lines are flattened to remove a part of each of the dielectric layers and a part of each of the laminated structures on a side away from the semiconductor substrate.

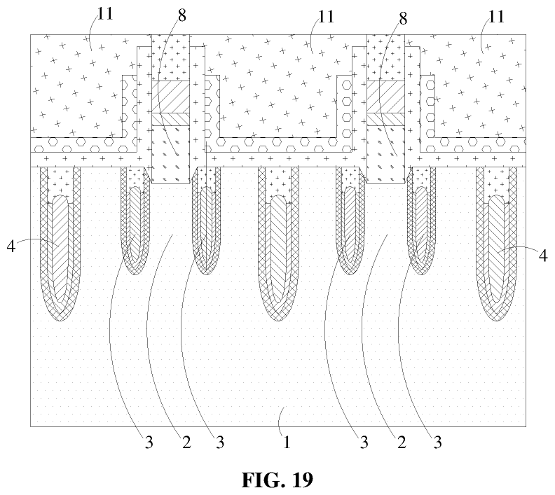

In the exemplary implementation mode, referring to FIG. 19, the dielectric layer 11 and the bit line 8 may be ground by the chemical mechanical grinder to remove part of the dielectric layer 11 and part of the top dielectric layer 54 without removing the first side wall 71 and the second side wall 91, so that the bit line 8 remains a step shape with the middle higher than the two side walls thereof. Even if a thin boundary layer is formed on each of the upper surfaces of the first side wall 71 and the second side wall 91 due to different polymers or shrinkage ratios, the laminated structure will form a barrier to avoid the decline of insulation performance The removed thickness is about 40 nm, so that the height of the remained dielectric layer 11 and bit line 8 is about 300 nm. Certainly, in other exemplary implementation modes of the disclosure, a part of the first side wall 71 may also be removed, so that the height of the first side wall 71 is the same as the height of the top dielectric layer 54 and the height of the dielectric layer 11. Even if a thin boundary layer is formed on each of the upper surfaces of the first side wall 71 and the second side wall 91 due to different polymers or shrinkage ratios, the boundary layer on the first side wall 71 will be removed, and the laminated structure and the first side wall 71 will also form a barrier of the second side wall 91 to avoid the decline of insulation performance.

Finally, the manufacturing method may also include the following operations. The sacrificial layer 16 in each of the second areas 152 is removed by etching to form capacitor contact holes. Capacitor contact plugs are formed in the capacitor contact holes.

The height of the first side wall 71 on the sidewall of the laminated structure 5 is lower than the height of the laminated structure 5, the height of the second side wall 91 is lower than the height of the first side wall 71, and the laminated structure 5 forms a bit line 8 with the first side wall 71 and the second side wall 91, so that the bit line 8 forms a step shape with the middle higher than both sides thereof. At this time, the spacing A between two adjacent bit lines 8 on a side close to the semiconductor substrate 1 is less than the spacing B between the two adjacent bit lines 8 on a side far away from the semiconductor substrate 1, so that the gap between the two adjacent bit lines 8 forms a structure with large top and small bottom. When the dielectric layer 11 is formed in the dielectric hole 10, it is not easy to form a void 13 on a side close to the semiconductor substrate 1, and the void 13 might be formed in the dielectric layer 11 on a side far away from the semiconductor substrate 1. Then, a part of the dielectric layer 11 and a part of the top dielectric layer 54 of the bit line 8 are removed, which causes the void 13 between the two adjacent bit lines 8 to be removed at the same time, so that there will be no short circuiting of the capacitor contact hole.

Moreover, a thin boundary layer 14 is formed between the subsequently refilled dielectric layer 11 and the surface of the top dielectric layer 54 due to different polymers or shrinkage ratios, but the boundary layer 14 will be removed when a part of the dielectric layer 11 and a part of the bit line 8 are removed. Therefore, the insulation performance will not be reduced, and meanwhile, the risk of parasitic capacitance will not be increased.

Furthermore, the exemplary implementation mode of the disclosure further provides a semiconductor device. The semiconductor device is manufactured by the above manufacturing method of the semiconductor device. Referring to FIG. 19, the semiconductor device may include a semiconductor substrate 1, laminated structures 5, side wall structures and dielectric layers 11. The semiconductor substrate 1 has a plurality of first areas 151 and a plurality of second areas 152 arranged alternately and adjacent to each other. The laminated structures 5 are arranged on the semiconductor substrate 1 and each intersect with the first areas 151 and the second areas 152. The side wall structures are arranged on sidewalls of the laminated structures 5, the laminated structure 5 and the side wall structure located in each of the first areas 151 are arranged in a step shape with a middle higher than both sides of the step shape, and the laminated structures 5 and the side wall structures form bit lines 8. The dielectric layers 11 are arranged on the semiconductor substrate 1 and each are located in the first area 151 between the bit lines 8. The dielectric layers 11 are connected with the bit lines 8 to form a plurality of capacitor contact holes.

In the exemplary implementation mode, the laminated structures 5 each may include a polysilicon layer 51, a first conductive layer 52, a second conductive layer 53 and a top dielectric layer 54. The polysilicon layer 51 is arranged on the semiconductor substrate 1. The first conductive layer 52 is arranged on a side, away from the semiconductor substrate 1, of the polysilicon layer 51. The second conductive layer 53 is arranged on a side, away from the semiconductor substrate 1, of the first conductive layer 52. The top dielectric layer 54 is arranged on a side, away from the semiconductor substrate 1, of the second conductive layer 53.

In the exemplary implementation mode, the side wall structures each may include a first side wall 71 and a second side wall 91. The first side wall 71 is arranged on a sidewall of the laminated structure 5, and a height of the first side wall 71 is less than a height of the laminated structure 5. The second side wall 91 is arranged on a sidewall of the first side wall 71, and a height of the second side wall 91 is less than the height of the first side wall 71.

In the exemplary implementation mode, the semiconductor device may also include a capacitor contact plug (not shown in the figure), which is arranged in the capacitor contact hole.

Compared with the related art, the beneficial effect of the semiconductor device provided in the exemplary implementation mode of the disclosure is the same as that of the manufacturing method of the semiconductor device provided by the above exemplary implementation mode, which will not be elaborated here.

Furthermore, the exemplary implementation mode further provides a storage device, which may include above described any semiconductor device. The specific structure of the semiconductor device has been described in detail above, so it will not be elaborated here. The storage device may also include a capacitor connected to a capacitor contact plug or the like.

Compared with the related art, the beneficial effect of the storage device provided in the exemplary implementation mode of the disclosure is the same as that of the storage device of the semiconductor device provided by the above exemplary implementation mode, which will not be elaborated here.

The features, structures or characters described above may be combined in one or more implementation modes in any proper manner, and the features discussed in the various embodiments are interchangeable if possible. In the descriptions above, many specific details are provided to fully understand the implementation modes of the disclosure. However, those skilled in the art will realize that: the technical solutions of the disclosure may be practiced without one or more of the described specific details, or other methods, parts, materials and the like may be adopted. In other cases, known structures, materials or operations will not be shown or described in detail to avoid obscuring aspects of the disclosure.

The terms “about” and “approximately” used in this specification usually mean that a feature is within 20%, preferably within 10%, and more preferably within 5%, of a given value or range. The quantity given here is an approximate quantity, which means that the meaning of “about”, “approximately”, “roughly” and “probably” may still be implied without specific description.

Although this specification uses relative terms such as “upper” and “lower” to describe the relative relationship of a component to another component shown in the figures, these terms are used in this specification only for convenience, for example, according to the example direction described in the drawings. It is understood that, if the device of the figures is turned upside down, the “upper” component will become “lower” component. Other relative terms, such as “high”, “low”, “top”, “bottom”, etc., also have similar meanings. When a structure is “on” another structure, it may mean that this structure is integrally formed on another structure, or that this structure is provided “directly” on another structure or this structure is provided “indirectly” on another structure through a further structure.

In the specification, the wordings “a”, “an”, “the”, and “said” are used to indicate one or more elements/components/etc. The wordings “include”, “comprise” and “have” are used to express an open sense of including and to indicate that additional elements/components/and the like may exist in addition to the listed elements/components/and the like; and the wordings “first”, “second” and “third” are used only as marks, not intended to limit the number of the objects they refer to.

It can be understood that, application of the disclosure is not limited to detailed structures and arrangement modes of parts disclosed in the specification. The disclosure may have other implementation modes, and may be realized and executed in many forms. The foregoing modifications and improvements shall fall within the scope of the disclosure. It can be understood that, the disclosure disclosed and limited in the specification extends to all replaceable combinations of two or more independent features mentioned or apparent in the text and/or the drawings. All these different combinations form multiple replaceable aspects of the disclosure. All the implementation modes of the specification illustrate the known best mode for realizing the disclosure, and allow those skilled in the art to utilize the disclosure.

1. A manufacturing method of a semiconductor device, comprising:
providing a semiconductor substrate having a plurality of first areas and a plurality of second areas arranged alternately and adjacent to each other;
forming, on the semiconductor substrate, laminated structures each intersecting with the first areas and the second areas;
forming side wall structures on surfaces of the laminated structures, wherein the side wall structures and the laminated structures constitute bit lines;
filling a sacrificial layer having a height greater than or equal to a height of the bit lines;
etching each of the side wall structures in each of the first areas, so that the laminated structure and the side wall structure form a step shape with a middle higher than both sides of the step shape;
forming, on the semiconductor substrate in the first areas, dielectric layers having a height greater than or equal to the height of the bit lines; and
flattening the dielectric layers and the bit lines to remove a part of each of the dielectric layers and a part of each of the laminated structures on a side away from the semiconductor substrate.

2. The manufacturing method of the semiconductor device according to claim 1, wherein the bit lines each comprises a protective layer located on a side, away from the semiconductor substrate, of the laminated structure.

3. The manufacturing method of the semiconductor device according to claim 2, wherein said forming the side wall structures on the surfaces of the laminated structures comprises:
forming first side walls on sidewalls and top surfaces of the laminated structures; and
forming second side walls on sidewalls and top surfaces of the first side walls.

4. The manufacturing method of the semiconductor device according to claim 3, wherein the material of the sacrificial layer and the material of the protective layer are the same.

5. The manufacturing method of the semiconductor device according to claim 4, wherein said etching each of the side wall structures in each of the first areas comprises:
flattening the sacrificial layer, to expose a side, away from the semiconductor substrate, of the second side wall; and
etching the first side wall and the second side wall to expose the protective layer.

6. The manufacturing method of the semiconductor device according to claim 5, said etching each of the side wall structures in each of the first areas further comprises:
etching the first side wall by taking the protective layer as a mask and by selecting an etching process in which an etching rate of the first side wall is greater than an etching rate of each of the second side wall and the sacrificial layer, so that a height of the first side wall is lower than a height of the laminated structure; and
etching the second side wall, the protective layer and the sacrificial layer by selecting an etching process in which the etching rate of the sacrificial layer is greater than the etching rate of the second side wall and the etching rate of the second side wall is greater than the etching rate of the first side wall, so that a height of the second side wall is lower than the height of the first side wall, and removing the protective layer and the sacrificial layer in the first area to form a dielectric hole.

7. The manufacturing method of the semiconductor device according to claim 6, wherein a height difference between the first side wall and the laminated structure is greater than or equal to 30 nm and less than or equal to 50 nm, and a height difference between the first side wall and the second side wall is greater than or equal to 30 nm and less than or equal to 50 nm.

8. The manufacturing method of the semiconductor device according to claim 6, after forming the dielectric layer in the dielectric hole, further comprising:
removing the sacrificial layer in each of the second areas to form capacitor contact holes; and
forming capacitor contact plugs in the capacitor contact holes.

9. The manufacturing method of the semiconductor device according to claim 1, wherein said forming the laminated structures comprises:
forming a polysilicon material layer on a surface of the semiconductor substrate;
forming a first conductor material layer on a surface of the polysilicon material layer;
forming a second conductor material layer on a surface of the first conductor material layer;
forming a top dielectric material layer on a surface of the second conductor material layer; and
etching the top dielectric material layer, the second conductor material layer, the first conductor material layer and the polysilicon material layer to form the laminated structures in a strip shape.

10. A semiconductor device, comprising:
a semiconductor substrate, provided with a plurality of first areas and a plurality of second areas arranged alternately and adjacent to each other;
laminated structures, arranged on the semiconductor substrate and each intersecting with the first areas and the second areas;
side wall structures, arranged on sidewalls of the laminated structures, wherein the laminated structure and the side wall structure located in each of the first areas are arranged in a step shape with a middle higher than both sides of the step shape, and the laminated structures and the side wall structures form bit lines; and
dielectric layers, arranged on the semiconductor substrate and each located in the first area between the bit lines, wherein the dielectric layers are connected with the bit lines to form a plurality of capacitor contact holes.

11. The semiconductor device according to claim 10, wherein the side wall structures each comprises:
a first side wall, arranged on a sidewall of the laminated structure, and having a height less than a height of the laminated structure; and
a second side wall, arranged on a sidewall of the first side wall and having a height less than the height of the first side wall.

12. A storage device, comprising a semiconductor device,
the semiconductor device comprising:
a semiconductor substrate, provided with a plurality of first areas and a plurality of second areas arranged alternately and adjacent to each other;
laminated structures, arranged on the semiconductor substrate and each intersecting with the first areas and the second areas;
side wall structures, arranged on sidewalls of the laminated structures, wherein the laminated structure and the side wall structure located in each of the first areas are arranged in a step shape with a middle higher than both sides of the step shape, and the laminated structures and the side wall structures form bit lines; and
dielectric layers, arranged on the semiconductor substrate and each located in the first area between the bit lines, wherein the dielectric layers are connected with the bit lines to form a plurality of capacitor contact holes.

13. A storage device according to claim 12, wherein the side wall structures each comprises:
a first side wall, arranged on a sidewall of the laminated structure, and having a height less than a height of the laminated structure; and
a second side wall, arranged on a sidewall of the first side wall and having a height less than the height of the first side wall.
